(19) United States
(12) Patent Application Publication
(10) Pub. No.: US 2003/0041295 A1
(43) Pub. Date: Feb. 27, 2003

(54) Method of defects recovery and status display of dram

(76) Inventors: Chien-Tzu Hou, Fremont, CA (US); Hsiu-Ying Hsu, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/935,650

(22) Filed: Aug. 24, 2001

(51) Int. Cl. G11C 29/00

(52) U.S. Cl. 714/710

(57) ABSTRACT

A method of defects recovery and status display of dynamic random access memory(DRAM), which mainly start time test through a monitor program, and predetermine a spare memory page which serves as temporary storage of internal data while the memory page is tested, the internal data of the memory page which will be tested are duplicated to the predetermined memory page, and then a table of look-aside buffer(TLB) is built to map the location of the tested memory page to the predetermined spare memory page, the tested memory page is re-directed to the predetermined spare memory page through TLB, which makes normal access be re-directed to the spare memory page; while any memory page with defects is detected, the monitor program will continuously block the said tested memory page, and any access operation for the said memory page will re-direct to the predetermined spare memory page according to TLB, and LCD will be driven to display the message such as testing frequency, intact report, detected fault, sum of memory usage, and actual memory size, etc., which make DRAM maintain in normal access and with high-level data integrity though there is error existed.

### BACKGROUND OF THE INVENTION

(1) Field of the Invention

The invention relates to a method of defects recovery and status display of dynamic random access memory(DRAM), and more particularly to a design of redirecting the failed and inactive memory page in DRAM to a predetermined spare memory, and displaying various message about status of the memory, which make it possible that the memory can operate properly while there are faults existed.

(2) Description of the Prior Art

Whereas the requirement for the storage capacity of DRAM has increased up to 10⁶ times during the past 25 years, due to the introduction of one transistor one capacitor storage cell, shrink ratio of trench capacitor and stack capacitor and its introduction, and the application of various technology in shrink ratio of transistor, the size of DRAM storage cell has been substantially reduced, and each chip is provided with higher storage cell density. Unfortunately, the prior described processing costs of minimization rise rapidly with the increasing of the density. Another disadvantage about the high-density DRAM is that electron punch-through phenomenon is easily happened even in employing yield DRAM, further increase the decay rate, and thus reduce the integrity of data stored thereof, which is major harm to high-level server memory which demands for high-level completeness of data maintenance.

Referring to stability of DRAM, wherein product life cycle is shown in FIG. 1 as a bathtub curve, which is roughly divided to three period as infant mortality, useful life, and wearout. During the infant mortality period, due to DRAM is formed through wafer slicing, testing, and package, various testing and healing (such as laser or capacitor, etc.) must be applied to prevent the defects(such as impurity deposited, etc.) produced during processing, which make DRAM cannot access normally, and then the yield products can be obtained. Those inevitable costs of testing and healing account for extremely high ratio in production costs and cannot be reduced.

Though the yield products produced from prior steps can operate normally, but still can be unstable. For this reason, DRAM manufacturers usually further proceed with bum-in test during the infant mortality period, which utilizes the environment of high temperature and high voltage to urge DRAM to enter into useful life period earlier, and thus consumers can get DRAM with fine work stability. After users have used DRAM for a period, it will gradually get aging into wearout period, due to the material per se and the influence of voltage and temperature which the work place applies. The unstability of DRAM rises, which easily makes system crash and operation unstable. During this period, while users find out above phenomenon happened in the system, most of them will change to a new one, thus the product life of DRAM is over.

While in fact, due to DRAM is divided into a plurality of basic storage unit, the aging phenomenon of DRAM is induced by the aging of memory units, which makes data cannot be accessed normally, most system use error correction code (ECC) to inspect the data access failure and correct it. Basically, ECC detects n bits, and corrects m bits (m≦n). For example, DRAM with 64 bits bus can use 8 bits ECC, i.e. it use 8 bits ECC to do failure detection and correction. But the data bits are appended with 8 bits ECC, which prolong data length for 8 bits and make costs increase for ⅛. Therefore, to achieve the object of detection and correction, and consideration of costs for the manufacturers, the adoption of 8 bits ECC would be more proper, which define the ECC as binary detection and 1 bit correction. If single bit error transfers to binary error, the unrecoverable hardware error will happen.

To prevent that the single bit error transfers to binary error, until now, while ECC is detecting the data, normal operation of system will halt temporarily and a specified program will be executed to inspect if there is data error existed or not, and immediately recover it while single bit error is discovered. But the occurrence of single bit error means that the said DRAM operates unstably, thus makes the system execute under unstable state, and though the address where error occurs is recovered, it cannot ensure that it would not happen again, and it may transfer to binary error due to unstability, which causes DRAM cannot operate and must be changed. Due to the operation of ECC is totally executed by hardware, the user cannot know any about the operation status of DRAM. In this case, system must often be shutdown, changed, and restarted, but in most work environment the system is not permitted to be shutdown, especially for the intranet server in large enterprise, if it shutdowns, the interior work will halt, which increase the cost during shutdown period and the maintenance cost of server memory.

### SUMMARY OF THE INVENTION

Whereas, the major object of the present invention is to provide a method of defects recovery and status display of DRAM, which provides real time test and recovery of memory page during DRAM operation, and make DRAM manufacturers save cost during the infant mortality period. Thus the cost of test and recovery can be saved, the DRAM would not crash in system due to one memory unit not working normally, which can prolong the product usage period of DRAM, especially can maintain normal access operation in server system which can not be shutdown and has DRAM error with it.

In the present invention a plurality of spare memory pages are reserved which serve as temporary storage of internal data while the memory pages are tested. The DRAM data of a tested memory page is duplicated to one of the spare memory page, and then a table of look-aside buffer(TLB) is built to map the location of the tested memory page to the predetermined spare memory page. The tested memory pages are redirected to the predetermined spare memory pages through TLB, in the meantime, the monitor program also block access operation of tested pages temporarily; while any memory page with defects is detected, the monitor program will continuously block the tested memory page, and any access operation for the said memory page will be re-directed to the predetermined spare memory page according to TLB, which allocates the data access operation to the spare memory page, and makes DRAM maintain normal operation no matter there is an error or not.

Another object of the present invention is that a LCD is driven through CPU to display the message such as testing frequency, intact report, detected fault, sum of memory usage, and actual memory size, etc., making users can easily control and observe DRAM's status.

Further object of the present invention is while the data are duplicated to the spare memory page, the ECC inspection procedure is proceeded through the monitor program. If there is a single bit or binary error happened, the said inspection procedure records whether the said memory page is unstable or unrecoverable, and then strengthen inspection to prevent single bit from transferring to binary error.

Below describes detailed structure design and technique principle of the invention, referring to appended drawings, will further understand the characteristics of the present invention, wherein:

### BRIEF DESCRIPTION OF THE DRAWINGS

FIG. 1 is a bathtub curve of DRAM;

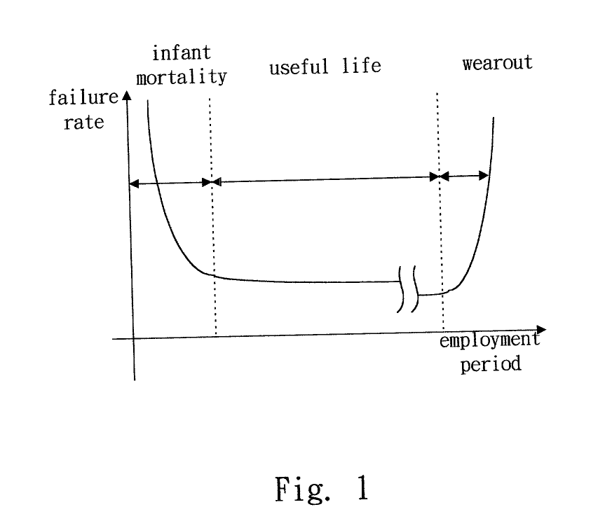

FIG. 2 is a diagram of memory module structure of the present invention; and

FIG. 3 is an operation steps flow of the present invention.

### DESCRIPTION OF THE PREFERRED EMBODIMENT

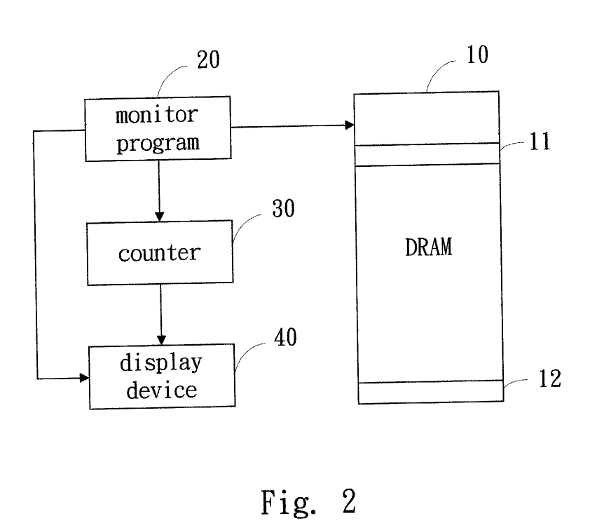

Please refer to FIG. 2, the present invention can be accomplished directly through hardware or with added software, the structure of the said DRAM 10 includes:

a monitor program 20 which regularly inspect the DRAM data integrity;

a counter 30 which serves as a timer for the monitor program20;

a display device 40 (in the embodiment, LCD device is employed, or display directly through monitor) which is used to display all DRAM 10 related information.

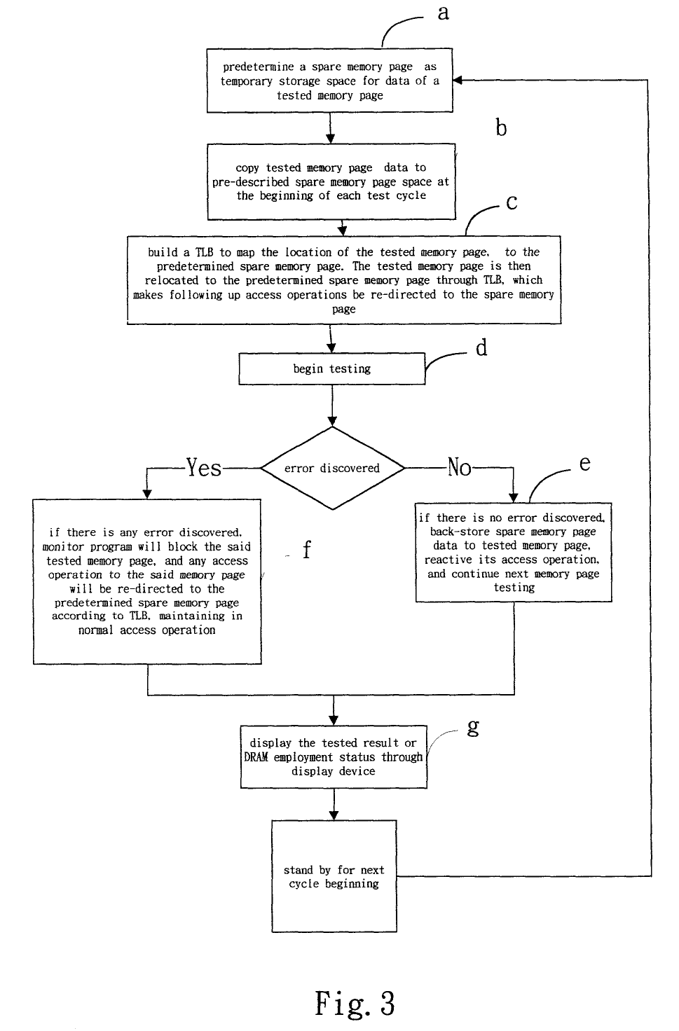

Referring to FIG. 3, after each cycle start, monitor program 20 will predetermine a spare memory page as the temporary storage space of the tested memory page 11 (due to DRAM 10 address is organized by continuous memory pages in sequence, the spare pages is usually located in the bottom of memory pages), the data of the memory page 11 which will be tested are copied to the predetermined spare memory page 12, and then a table of look-aside buffer(TLB) is built to map the location of the tested memory page 11, to the predetermined spare memory page 12. The accesses to the tested memory page 11 is then relocated to the predetermined spare memory page 12 through TLB. Therefore, the original access operation of the system would not be affected. In the mean time the monitor program 20 also blocks the tested memory page temporarily, and starts proceeding the said memory page testing.

In the embodiment, the monitor program 20 checks page by page; if there is no error discovered, data of the said page will be back-stored to tested memory page 11 from predetermined spare memory page 12, continues its normal access operation, and start next memory page testing.

In the invention, the pre-described memory page inspection can be achieved through following method:

1. Inspection method which ECC is not included: mainly through normal hardware test, which operates the continuous operation of write, then read to memory page, testing if the access is normal. If failed, it implies that there is error happened in the said memory page.

2. Inspection method which ECC is included: the monitor program copies the information to spare memory page while proceeds inspection procedure. If there is single bit error happened, the said inspection procedure will record whether the said memory page is unstable or unrecoverable, and then strengthen inspection. If the single bit error happen again, the tested memory page will be blocked to prevent single bit error prevailing to un-recoverable double bit error. All the following up accesses to the tested page will be re-directed to the spare memory page according to the TLB.

While any tested memory page 11 in DRAM 10 is detected with defects (such as pre-described electron punch through, etc.), or any error happened, the monitor program 20 will continuously block the said tested memory page 11, and any access operation for the said memory page 11 will be re-directed to the spare memory page 12 according to TLB, hence original spare memory page 12 will keep in a occupied state. To continue proceeding next memory page test, the monitor program 20 must further predetermine another spare memory page 12 to store data from next tested memory page. In the mean time, display device 40 (LCD) will be driven to display the message such as testing frequency, intact report, detected fault (example: ECC error time, recoverable number, unrecoverable number), sum of memory usage, and actual memory size, etc., which make user can master the situation of DRAM 10.

Furthermore, content of display device 40 (LCD) will keep unchanged until next testing cycle.

Summarizing above description can generalize steps as follows:

a. predetermine a spare memory page 12 as temporary storage space for data of a tested memory page 11;

b. copy tested memory page 11 data to pre-described spare memory page 12 space at the beginning of each test cycle;

c. build a TLB to map the location of the tested memory page 11, to the predetermined spare memory page 12. The tested memory page 11 is then relocated to the predetermined spare memory page 12 through TLB, which makes following up access operations be re-directed to the spare memory page 12;

d. begin testing;

e. if there is no error discovered, back-store spare memory page 12 data to tested memory page 11, reactive its access operation, and continue next memory page testing;

f. if there is any error discovered, monitor program 20 will block the said tested memory page 11, and any access operation to the said memory page will be re-directed to the predetermined spare memory page according to TLB, maintaining in normal access operation;

g. display the tested result or DRAM employment status through display device.

Concluding above description, the invention provides with following advantages:

1. After DRAM manufacturers finishing package procedure, there needs few test. the main testing process can be proceeded in users' system, if there is an error happened, it will be recovered instantly, maintaining normal system operation.

2. When there is a DRAM error occurs during a server operation that can not be shutdown. The present invention can maintain DRAM in normal operation. The system status can also be displayed through a LCD displayer, thus reduces the maintenance cost of a server memory.

3. While using ECC for inspecting, CPU still can operate normally, making no influence on the execution efficiency of system.

Concluding the above description, the invention provides method of defects recovery and status display of DRAM, which proceed with real time blocking and instant recovery through a monitor program. In the mean time, display the DRAM's current status through display device, maintain normal access and high-level data integrity even there is error happened. Summarizing above description, the invention provides with effective solution and strategy for improving the stability of conventional memory, which needs to replace a whole memory module while a single defects is discovered.

Whereas above described method about technology, drawings, program, or control, etc., are only one preferred embodiment of the present invention, those equivalent variation or modification in the technology, or similar fabrication which picks up part function of the claims according to the present invention, should be included in the criterion of the invention, but the employment scope of the invention is not limited.

What is claimed is:

1. A method of defects recovery and status display of DRAM which mainly through a monitor program to regularly detect the operation status of information integrity stored in various memory page of DRAM, and to recover in real, wherein includes steps below:
a. predetermine a spare memory page as temporary storage space for a tested page data;
b. copy tested memory page data to pre-described spare memory page at the beginning of each test cycle;
c. build a TLB to map the location of the tested memory page to the predetermined spare memory page, the tested memory page is relocated to predetermined spare memory page through TLB, which redirect follow up access operations to the spare memory page;
d. if there is no error occurs, back-store spare memory page data to the tested memory page, return the tested page to normal access operation and continue next memory page testing;
e. if there is any error occurs, monitor program will constantly block the said tested memory page, and any access operation to the said memory page will be redirected to the predetermined spare memory page according to TLB
f. display the tested result through display device.

2. A method of defects recovery and status display of DRAM according to claim 1, wherein the said monitor program tests memory page is a page monitor program which inspects page by page.

3. A method of defects recovery and status display of DRAM according to claim 1, wherein the said testing cycle of monitor program is supplied by a counter.

4. A method of defects recovery and status display of DRAM according to claim 1, wherein the said display device is liquid crystal device (LCD), monitor, etc.

5. A method of defects recovery and status display of DRAM according to claim 1, wherein the said result displayed in step f includes: testing frequency, intact report, detected fault, sum of memory usage, and actual memory size, etc., which enables users real time master the employment status of DRAM.

6. A method of defects recovery and status display of DRAM according to claim 1, wherein the said content displayed in display device is keeping unchanged until the beginning of next testing cycle.

7. A method of defects recovery and status display of DRAM according to claim 1, wherein during the said step e, the tested memory page keeps in occupied state, until next memory page is tested, the monitor program will predetermine another spare memory page for tested memory page to keep on storing information, in the mean time, TLB will record memory page in which defects are discovered, and the corresponding relationship between next tested memory page and predetermined memory page.

8. A method of defects recovery and status display of DRAM according to claim 1, wherein the said memory page inspection further includes inspection method for which error correction code(ECC) is not included, mainly through normal hardware test, which operates the continuous operation of write, then read to memory page, testing if the access is normal, if failed, it implies that there is error happened in the said memory page.

9. A method of defects recovery and status display of DRAM according to claim 1, wherein the said memory page inspection further includes inspection method for which error correction code is included, which is proceeded with above described monitor program copying information to spare memory page in the same time, if there is single bit error happened, it will be recorded that the said memory page is unstable, and then recover it and strengthen the inspection; if single bit error happens again, then step e described in claim 1 will be executed to prevent single bit from transferring to binary error; if the error disappears, then step d described in claim 1 will be executed.
